(19) United States
(12) Patent Application Publication
(10) Pub. No.: US 2024/0206149 A1
(43) Pub. Date: Jun. 20, 2024

(54) SEMICONDUCTOR DEVICE AND MANUFACTURING METHOD THEREOF

(71) Applicant: Samsung Electronics Co., Ltd., Suwon-si (KR)

(72) Inventors: Minjun Lee, Suwon-si (KR); Hyoseok Kim, Suwon-si (KR); Yongseok Kim, Suwon-si (KR)

(21) Appl. No.: 18/541,791

(22) Filed: Dec. 15, 2023

(30) Foreign Application Priority Data
Dec. 16, 2022 (KR) 10-2022-0177540

(51) Int. Cl. H10B 12/00

(52) U.S. Cl. CPC H10B 12/20

(57) ABSTRACT

A semiconductor device includes a source line extending in a first horizontal direction on a substrate, a channel layer extending in a vertical direction perpendicular to an upper surface of the substrate, and including a first end, a second end opposite to the first end, and a channel layer sidewall connecting the first end with the second end, the first end being disposed on the source line, a trap layer disposed on the channel layer sidewall, a gate insulating layer disposed on an outer surface of the trap layer, a word line disposed on at least one sidewall of the gate insulating layer and extending in a second horizontal direction crossing the first horizontal direction, a drain area disposed on the second end of the channel layer and including a metal or metal nitride, and a bit line disposed on the drain area and extending in the first horizontal direction.

### CROSS-REFERENCE TO RELATED APPLICATION

This application is based on and claims priority under 35 U.S.C. § 119 to Korean Patent Application No. 10-2022-0177540, filed on Dec. 16, 2022, in the Korean Intellectual Property Office, the disclosure of which is incorporated by reference herein in its entirety.

### BACKGROUND

The inventive concept relates to a semiconductor device and a manufacturing method thereof, and more particularly, to a capacitor-less semiconductor device and a manufacturing method thereof.

According to the downscaling of a semiconductor device, the size of an individual fine circuit pattern for implementing the semiconductor device is reduced to facilitate the downscaling. In particular, as the relative height, or aspect ratio, of a capacitor included in a dynamic random access memory (DRAM) device increases, the difficulty of a capacitor formation process increases and a refresh may be required to address leakage current through the capacitor. Accordingly, a capacitor-less DRAM device that does not experience leakage current through a capacitor has been proposed.

### SUMMARY

The inventive concept provides a semiconductor device with an improved sensing margin.

The inventive concept provides a manufacturing method of a semiconductor device with an improved sensing margin.

According to an aspect of the inventive concept, there is provided a semiconductor device including a source line extending in a first horizontal direction on a substrate, a channel layer extending in a vertical direction perpendicular to an upper surface of the substrate, and including a first end, a second end opposite to the first end, and a channel layer side wall extending from the first end to the second end, the first end being disposed on the source line, a trap layer disposed on the channel layer sidewall, a gate insulating layer disposed on the trap layer, a word line disposed on at least one sidewall of the gate insulating layer and extending in a second horizontal direction crossing the first horizontal direction, a drain area disposed on the second end of the channel layer and including a material having a work function equal to or smaller than 4.2 eV, and a bit line disposed on the drain area and extending in the first horizontal direction.

According to another aspect of the inventive concept, there is provided a semiconductor device including a source line extending in a first horizontal direction on a substrate, a word line disposed at a vertical level higher than the source line and extending in a second horizontal direction crossing the first horizontal direction, a gate insulating layer disposed on an inner wall of a word line opening penetrating the word line and extending in a vertical direction perpendicular to an upper surface of the substrate, a trap layer disposed on the gate insulating layer on the inner wall of the word line opening, a channel layer disposed on the trap layer on the inner wall of the word line opening and having a part in contact with an upper surface of the source line on a bottom portion of the word line opening, a drain area disposed at a vertical level higher than the word line, contacting an upper surface of the channel layer, and including a metal or metal nitride, and a bit line disposed on the drain area and connected in the first horizontal direction.

According to another aspect of the inventive concept, there is provided a semiconductor device including a plurality of source lines extending in a first horizontal direction on a substrate, a plurality of word lines respectively disposed at a vertical level higher than the plurality of source lines and extending in a second horizontal direction crossing the first horizontal direction, a plurality of bit lines respectively disposed at a vertical level higher than the plurality of word lines and extending in the first horizontal direction, and a plurality of memory units respectively disposed at intersections of the plurality of word lines and the plurality of bit lines, wherein each of the plurality of memory units includes a channel layer extending in a vertical direction perpendicular to an upper surface of the substrate and contacting an upper surface of each of the plurality of source lines, a trap layer disposed on an outer wall of the channel layer, a gate insulating layer disposed on an outer wall of the trap layer and surrounded by each of the plurality of word lines, and a drain area disposed on an upper surface of the channel layer and below each of the plurality of bit lines and including a metal or metal nitride.

### BRIEF DESCRIPTION OF THE DRAWINGS

Embodiments will be more clearly understood from the following detailed description taken in conjunction with the accompanying drawings in which:

FIG. 1 is a circuit diagram illustrating a semiconductor device according to some embodiments;

FIG. 2 is a layout diagram illustrating a semiconductor device according to some embodiments;

FIG. 3 is an enlarged layout diagram of a cell array area portion of FIG. 2 according to some embodiments;

FIG. 4 is a cross-sectional view taken along line A1-A1′ of FIG. 3 according to some embodiments;

FIG. 5 is a cross-sectional view taken along line A2-A2′ of FIG. 3 according to some embodiments;

FIGS. 6A to 6C are schematic diagrams illustrating a write operation, an erase operation, and current-voltage curves of a semiconductor device according to a comparative example;

FIG. 7 is a schematic diagram illustrating a read operation of a semiconductor device according to some embodiments;

FIGS. 8A and 8B are graphs illustrating current-voltage curves of a semiconductor device according to some embodiments;

FIGS. 9A to 9D are graphs illustrating current-voltage curves of semiconductor devices according to some embodiments;

FIG. 10 is a cross-sectional view taken along line A1-A1′ of FIG. 3 illustrating a semiconductor device according to some embodiments;

FIG. 11 is a cross-sectional view taken along line A1-A1′ of FIG. 3 illustrating a semiconductor device according to some embodiments.

FIG. 12 is a cross-sectional view taken along line A1-A1′ of FIG. 3 illustrating a semiconductor device according to some embodiments;

FIG. 13 is a layout diagram illustrating a semiconductor device according to some embodiments;

FIG. 14 is a cross-sectional view taken along line B1-B1′ of FIG. 13 according to some embodiments;

FIG. 15 is a cross-sectional view taken along line B2-B2′ of FIG. 13 according to some embodiments; and

FIGS. 16A to 22 are cross-sectional views illustrating a manufacturing method of a semiconductor device according to some embodiments. Specifically, FIGS. 16A, 17A, and 18A are plan views according to manufacturing processes, and FIGS. 16B, 17B, 18B, and 19 to 22 are cross-sectional views taken along line A1-A1′ of FIG. 16A.

### DETAILED DESCRIPTION OF THE EMBODIMENTS

Hereinafter, embodiments of the inventive concept will be described in detail with reference to the accompanying drawings.

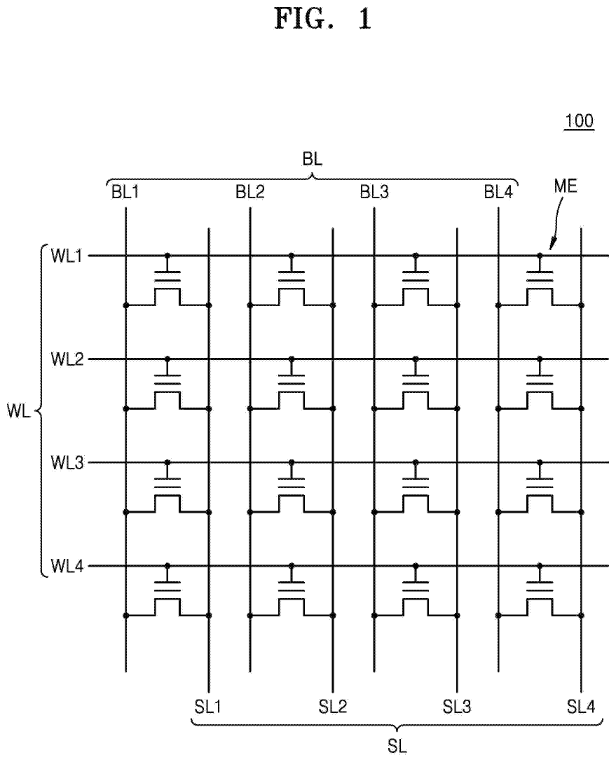

FIG. 1 is a circuit diagram illustrating a semiconductor device 100 according to some embodiments.

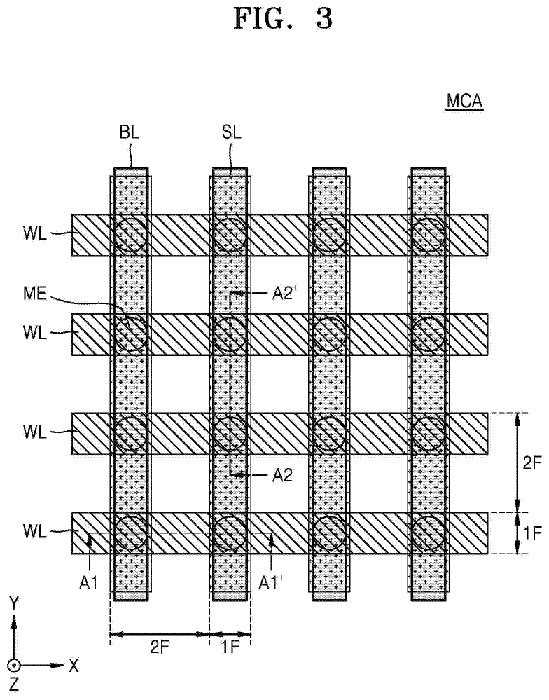

Referring to FIG. 1, the semiconductor device 100 may include a plurality of memory units ME disposed between a plurality of word lines WL and a plurality of bit lines BL. In the figures and the following description, the abbreviation ME will generically refer to one or more memory units ME, the abbreviation WL will generically refer to one or more word lines WL, the abbreviation BL will generically refer to one or more bit lines BL, and the abbreviation SL will generically refer to one or more source lines SL. In some discussions, when a specific memory unit ME, word line WL, bit line BL, or source line SL is being referred to, the abbreviation will include a number afterwards identifying the specific element. The plurality of memory units ME (e.g., memory cells, or memory transistors) may include charge trap type transistors. For example, the plurality of memory units ME may each be respectively disposed at an intersection of respective first to fourth word lines WL1, WL2, WL3, and WL4 and respective first to fourth bit lines BL1, BL2, BL3, and BL4. A gate of a memory unit ME may be connected to a word line WL, a drain terminal of the memory unit ME may be connected to a bit line BL, and a source terminal of the memory unit ME may be connected to a source line SL. In some embodiments, such as that shown in FIG. 3, the source lines SL, represented by first to fourth source lines SL1, SL2, SL3, and SL4, may extend lengthwise in a first horizontal direction, the bit lines BL, represented by first to fourth bit lines BL1, BL2, BL3, and BL4, may be also extend lengthwise in the same first horizontal direction, and each bit line BL may vertically overlap a respective source line SL, and be separated from the respective source line SL in a vertical direction, but embodiments are not limited thereto. An item, layer, or portion of an item or layer described as extending “lengthwise” in a particular direction has a length in the particular direction and a width perpendicular to that direction, where the length is greater than the width. Edges of each bit line BL may overlap in the vertical direction with edges of a respective source line SL, though FIG. 3 shows the edges separately for differentiation purposes. The semiconductor device 100 may be a capacitor-less dynamic random access memory (DRAM) device and the plurality of memory units may each be a DRAM memory cell in the form of a cross-point type single transistor.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Additionally, an ordinal number used as a label of an element does not indicate any particular order unless otherwise indicated.

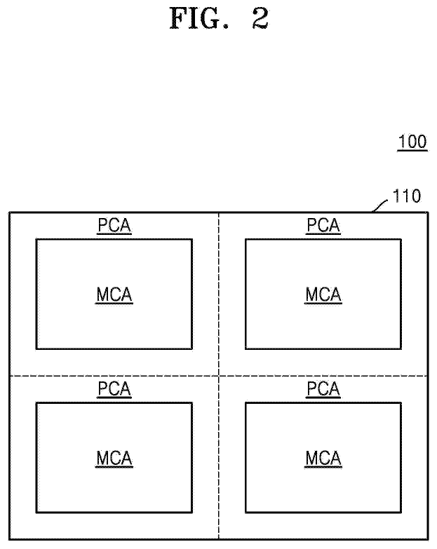

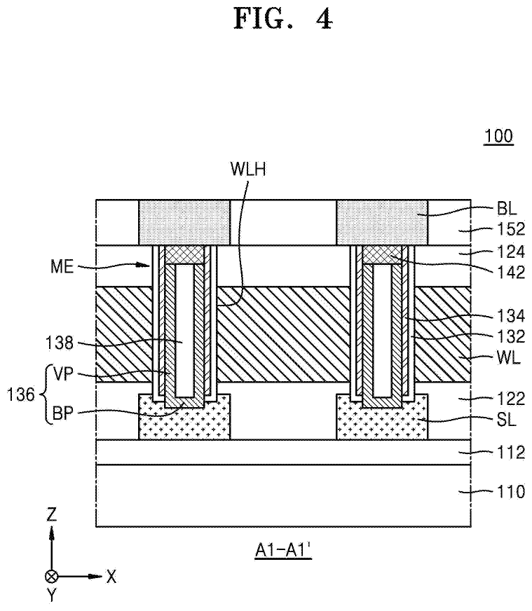

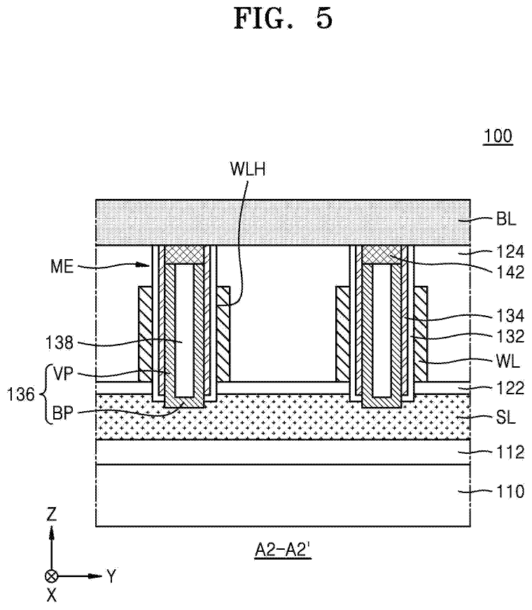

FIG. 2 is a layout diagram illustrating a semiconductor device 100 according to some embodiments. FIG. 3 is an enlarged layout diagram of a cell array area portion of FIG. 2. FIG. 4 is a cross-sectional view taken along line A1-A1′ of FIG. 3. FIG. 5 is a cross-sectional view taken along line A2-A2′ of FIG. 3.

Referring to FIGS. 2 to 5, the semiconductor device 100 may include a substrate 110 including a cell array area MCA and a peripheral circuit area PCA. In some embodiments, the cell array area MCA may be a memory cell area of a capacitor-less semiconductor device, and the peripheral circuit area PCA may be a core area or a peripheral circuit area of the capacitor-less semiconductor device. For example, the peripheral circuit area PCA may include a peripheral circuit transistor (not shown) transmitting a signal and/or power to a memory cell array included in the cell array area MCA. In some embodiments, peripheral circuit transistors (not shown) may configure various circuits such as a command decoder, control logic, an address buffer, a row decoder, a column decoder, a sense amplifier, and a data input/output circuit.

As shown in FIG. 3, a plurality of word lines WL extending in a first horizontal direction X as indicated in FIG. 3, a plurality of bit lines BL extending in a second horizontal direction Y as indicated in FIG. 3, and a plurality of source lines SL extending in the second horizontal direction

Y may be arranged on the cell array area MCA of the substrate 110. Individual memory units ME of a plurality of memory units ME may be each be respectively disposed at an intersection of a respective word line WL of the plurality of word lines WL and a respective bit line BL of the plurality of bit lines BL. As will be evident from FIGS. 4 and 5, the plurality of word lines, the plurality of bit lines, the plurality of source lines, and the plurality of memory units may each lie on a different, vertically offset horizontal plane. The plurality of memory units ME may include trap-type transistors or trap-type memory devices which trap electrons and/holes in a trap layer as will be described in further detail.

In some embodiments, the width of each of the plurality of word lines WL may be 1F (where F is a unitless unit for describing the relative size of elements), the pitch (i.e., the sum of width and space between adjacent word lines) of the plurality of word lines WL may be 2F, the width of each of the plurality of bit lines BL may be 1F, the pitch (i.e., the sum of width and space between adjacent bit lines BL) of the plurality of bit lines BL may be 2F, and the unit area forming one memory unit ME may be 4F2. Accordingly, one memory unit ME may have a cross-point type requiring a relatively small unit area, which may be advantageous to improve integration of the semiconductor device 100. It should be noted that FIG. 3 is not necessarily drawn to scale.

As shown in FIG. 4, a lower insulating layer 112 may be disposed on the substrate 110. The substrate 110 may be formed of and/or include silicon such as, for example, monocrystalline silicon, polycrystalline silicon, or amorphous silicon. In some embodiments, the substrate 110 may be formed of and/or include at least one of germanium (Ge), silicon germanium (SiGe), silicon carbide (SiC), gallium arsenide (GaAs), indium arsenide (InAs), or Indium Phosphide (InP). In some embodiments, the substrate 110 may include a conductive area, for example, a well doped with impurities, or a structure doped with impurities. The lower insulating layer 112 may include an oxide layer, a nitride layer, or a combination thereof.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion and does not necessarily mean disposed on the upper side of the object portion based on a gravitational direction. The term “contact,” “contacting,” “contacts,” or “in contact with,” as used herein, refers to a direct connection (i.e., touching) unless the context clearly indicates otherwise.

A source line SL extending in the second horizontal direction Y may be disposed on the lower insulating layer 112. In some embodiments, the source line SL may be formed of and/or include doped polysilicon such as, for example, p-type impurity-doped polysilicon. A first insulating layer 122 may be disposed on the lower insulating layer 112 to cover an upper surface and a sidewall of the source line SL.

The word line WL extending in the first horizontal direction X may be disposed on the first insulating layer 122. The word line WL may extend in a direction crossing the source line SL. The word line WL may be disposed at a higher vertical level than the source line SL such that a bottom surface of the word line WL may be spaced apart from the upper surface of the source line SL in the vertical direction Z as shown in FIG. 4. In some embodiments, the word line WL may be formed of and/or include doped polysilicon, titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. In some embodiments, the word line WL may include n-type impurity-doped polysilicon. In some embodiments, the word line WL may include a conductive layer and a barrier layer disposed on an outer surface of the conductive layer. The conductive layer and the barrier layer may be formed of and/or include at least one of Ti, TiN, Ta, TaN, W, WN, TiSiN, or WSiN.

As shown in FIG. 5, a second insulating layer 124 may be disposed on the first insulating layer 122 to cover an upper surface and a sidewall of the word line WL. The second insulating layer 124 may be disposed to have an upper surface disposed at a higher level than the upper surface of the word line WL. A bottom surface of the second insulating layer 124 may be disposed at the same level (e.g., coplanar) as that of the bottom surface of the word line WL.

A word line opening WLH may be formed in the word line WL to extend in the vertical direction Z through the second insulating layer 124, the word line WL, and the first insulating layer 122. The upper surface of the source line SL may be exposed at a bottom of the word line opening WLH. In some embodiments, the word line opening WLH may have a horizontal cross-sectional shape such as a circle, an ellipse, a rectangle, a rectangle with rounded corners, etc.

The memory unit ME may be disposed inside the word line opening WLH. The memory unit ME may include a gate insulating layer 132, a trap layer 134, a channel layer 136, a buried pillar 138, and a drain area 142.

The gate insulating layer 132 may be disposed on an inner wall defining the word line opening WLH, and a portion of an outer sidewall of the gate insulating layer 132 may be surrounded by the word line WL. In some embodiments, the gate insulating layer 132 may be formed of and/or include silicon oxide or a high-k dielectric material. The high-k dielectric material may include hafnium oxide, aluminum oxide, zirconium oxide, titanium oxide, or a combination thereof.

The trap layer 134 may be disposed on a wall of the gate insulating layer 132 within the word line opening WLH. The trap layer 134 may be a data storage layer in which holes or electrons provided by the channel layer 136 may be trapped when the memory unit ME is in a programmed or erased state. In some embodiments, the trap layer 134 may be formed of and/or include silicon nitride, hafnium oxide, aluminum oxide, yttrium oxide, or a combination thereof.

The channel layer 136 may be disposed on a wall of the trap layer 134 within the word line opening WLH. In some embodiments, the channel layer 136 may have a cylindrical shape extending in the vertical direction Z. The channel layer 136 may include a bottom portion BP disposed on the upper surface of the source line SL and a vertical extension portion VP integrally connected to the bottom portion BP and extending in the vertical direction Z. A portion of the channel layer 136 disposed on the upper surface of the source line may be disposed below a top-most surface of the source line. An outer sidewall of the vertical extension part VP may be covered by the trap layer 134 and may contact the trap layer 134. The channel layer 136 may be formed of and/or include at least one of polysilicon, silicon germanium, gallium arsenide, gallium nitride, indium phosphide, graphene, boron nitride, CuS₂, CuSe₂, WSe₂, MoS₂, MoSe₂, WS₂, indium zinc oxide, zinc tin oxide, yttrium zinc oxide, indium gallium zinc oxide, etc.

In some embodiments, the buried pillar 138 may be disposed on an inner sidewall of the channel layer 136. The buried pillar 138 may extend in the vertical direction Z inside the word line opening WLH and may have an upper surface disposed at the same level as an upper surface of the channel layer 136. The buried pillar 138 may be formed of and/or include silicon oxide or silicon nitride.

The drain area 142 may be disposed on the vertical extension portion VP of the channel layer 136. The drain area 142 may be disposed between the channel layer 136 and the bit line BL. In some embodiments, the drain area 142 may be disposed inside the word line opening WLH, and an outer sidewall of the drain area 142 may be surrounded by the trap layer 134. For example, a bottom surface of the drain area 142 may have a flat bottom profile so as to contact both the upper surface of the channel layer 136 and the upper surface of the buried pillar 138 disposed at the same vertical level. The bottom and top surfaces or boundaries of the drain area 142 may be located at a top surface of the channel layer 136 and a bottom surface of the bit line BL respectively, and a side surface or sidewall of the drain area 142 may be located at an inner side surface of trap layer 134.

In some embodiments, the drain area 142 may be formed of and/or include a metal or metal nitride having a work function equal to or smaller than 4.2 electron volts (eV). In some embodiments, the drain area 142 may be formed of and/or include at least one of titanium nitride (TiN), aluminum (Al), thallium (TI), indium (In), cadmium (Cd), hafnium (Hf), manganese (Mn), tantalum (Ta), or zirconium (Zr). In some embodiments, the drain area 142 consists of a material having a work function equal to or smaller than 4.2 electron volts (eV).

The bit line BL extending in the second horizontal direction Y may be disposed on the drain area 142, and a third insulating layer 152 may be disposed on the sidewall of the bit line BL. The bit line BL may be formed of and/or include Ti, TiN, Ta, TaN, W, WN, TiSiN, WSiN, polysilicon, or a combination thereof.

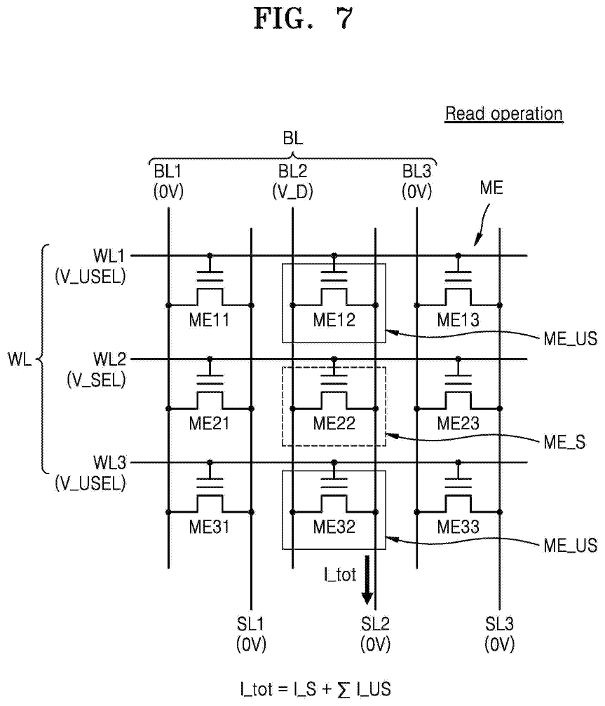

In some embodiments, the memory unit ME may constitute a cross-point type capacitor-less DRAM device. As will be described in reference to FIGS. 7-9D, the memory unit ME may write, program, erase, or read data by trapping electrons or holes transferred from the channel layer 136 to the trap layer 134 at high speed by application of a gate voltage.

In some embodiments, the drain area 142 of the memory unit ME includes a metal or metal nitride having the work function equal to or smaller than 4.2 eV, and thus, in a programming or writing operation, electrons provided from the source line SL and the drain area 142 to the trap layer 134 through the channel layer 136 may be trapped at high speed in a bulk programming manner. Also, in an erase operation, holes provided from the drain area 142 to the trap layer 134 through the channel layer 136 may be trapped at high speed in a bulk erase manner. The drain area 142 may also be described as a drain cap, which caps the cylinder formed by the channel layer 136 and buried pillar 138.

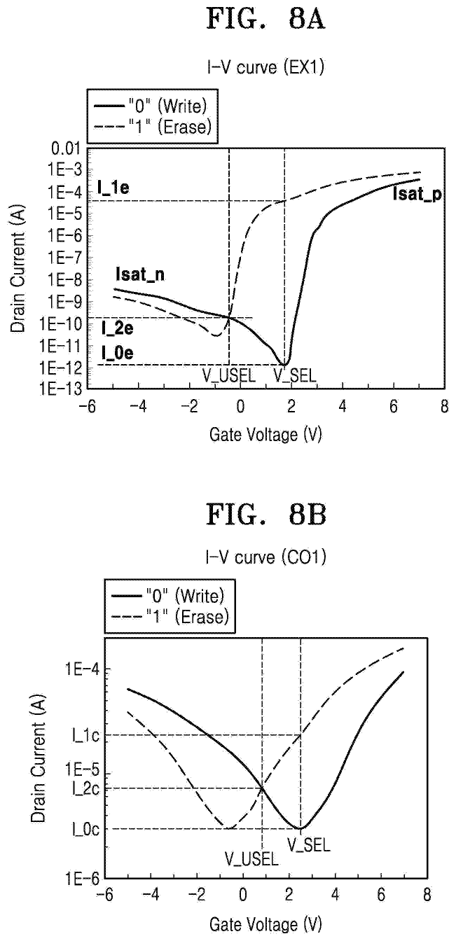

Also, the drain area 142 of the memory unit ME which includes a metal or metal nitride having the work function equal to or smaller than 4.2 eV may exhibit an asymmetrical current-voltage curve as shown in FIG. 8A. Accordingly, as will be described hereafter, the semiconductor device 100 may have an improved sensing margin for memory operations in an array including the plurality of memory units ME relative to a semiconductor device having memory units with a symmetrical current-voltage curve.

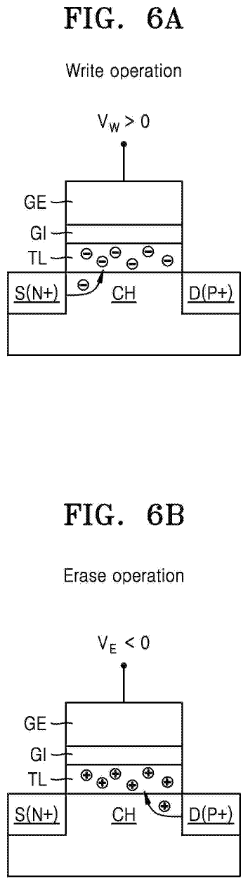

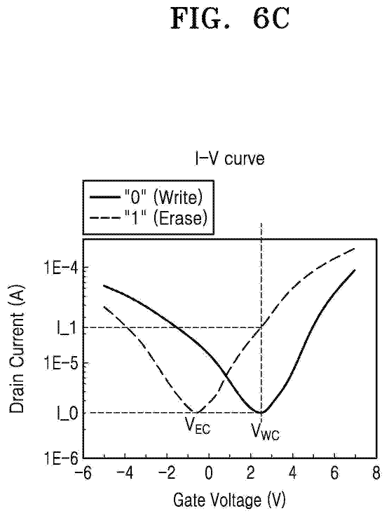

FIGS. 6A to 6C are schematic diagrams illustrating a write operation, an erase operation, and current-voltage curves of a semiconductor device according to a comparative example. The comparative example of FIGS. 6A to 6C are provided to compare memory operations in a semi-conductor device having a symmetrical current-voltage curve.

Referring to FIGS. 6A to 6C, the semiconductor device according to the comparative example has a structure in which a trap layer TL, a gate insulating layer GI, and a gate electrode GE are stacked on a channel CH, a source S includes an n+ dopant-doped semiconductor material, and a drain D includes a p+ dopant-doped semiconductor material.

As shown in FIG. 6A, in a write operation (or in a programming operation, e.g., setting the “0” state), a write voltage V_{W} having a positive value is applied to the gate electrode GE, and electrons are trapped into the trap layer TL.

As shown in FIG. 6B, in the erase operation (e.g., setting the “1” state), an erase voltage V_{E} having a negative value is applied to the gate electrode GE, and holes may be trapped into the trap layer TL from the drain D.

As shown in FIG. 6C, an I-V curve for the semiconductor device after the write operation in the comparative example has a left-right symmetrical profile with respect to a write reference voltage V_{WC}, and an I-V curve for the semiconductor device after the erase operation has a left-right symmetrical profile with respect to an erase reference voltage V_{EC}.

When performing a read operation of a memory cell, including the comparative example and in embodiments of the current inventive concept, a read operation may be performed using the same voltage as a write reference voltage V_{WC}. For example, whether a memory cell is in a “0” state or a “1” state (previously written or previously erased) may be sensed by applying a read voltage equal to or similar to the write reference voltage V_{WC} to the memory cell and reading (e.g., sensing) a current value. For example, because a memory cell in which the write operation is completed has a high threshold voltage, when the write reference voltage V_{WC} is applied to the gate electrode GE, a first current I_0, which is a relatively low current value, may flow. On the other hand, because the memory cell in which the erase operation is completed has a low threshold voltage, when the write reference voltage V_{WC} is applied to the gate electrode GE, a second current I_1, which is a relatively high current value, may flow. Thus, it is possible to determine the state of the memory cell based on the relative magnitude of the current measured when applying V_{WC} to the gate electrode.

Because the semiconductor device according to the comparative example has a structure in which the trap layer TL contacts the channel CH, the trap speed of electrons or holes may be relatively high, and the write operation and erase operation of the semiconductor device may be performed at relatively high speed. However, because the semiconductor device according to the comparative example exhibits a current-voltage curve having a symmetrical profile, when a plurality of memory units are arranged in an array, a difference between a current value of a selected memory unit and a current value of an unselected memory unit is relatively small, which is a problem in that the sensing margin of the semiconductor device is low.

FIG. 7 is a schematic diagram illustrating a read operation of a semiconductor device according to some embodiments.

Referring to FIG. 7, in the semiconductor device according to some embodiments, a plurality of memory units ME or a plurality of trap-type transistors are arranged in an array. For example, first to third memory units ME11, ME12 and ME13 are connected to the first word line WL1, fourth to sixth memory units ME21, ME22 and ME23 are connected to the second word line WL2, and seventh to ninth memory units ME31, ME32, and ME33 are connected to the third word line WL3. In addition, the first, fourth, and seventh memory units ME11, ME21, and ME31 are connected to the first bit line BL1, the second, fifth, and eighth memory units ME12, ME22, and ME32 are connected to the second bit line BL2, and the third, sixth, and ninth memory units ME13, ME23, and ME33 are connected to the third bit line BL3.

Because each memory unit ME of the plurality of memory units ME is connected to an intersection between the plurality of word lines WL and the plurality of bit lines BL, a current may also flow to an unselected memory unit ME_US that shares a word line WL or a bit line BL with a selected memory unit ME_S. For example, when the fifth memory unit ME22 disposed at the intersection of the second word line WL2 and the second bit line BL2 is the selected memory unit ME_S, a current may flow to memory units ME such as the second memory unit ME12 and the eighth memory unit ME32 connected to the second bit line BL2. Thus, in this example, second memory unit ME12 and eighth memory unit ME32 may correspond to the unselected memory unit ME US.

In the read operation, a selected voltage V_SEL may be applied to the word line WL (e.g., the second word line WL2) connected to the selected memory unit ME_S, and an unselected voltage V_USEL may be applied to the word line WL (e.g., the first and third word lines WL1 and WL3) connected to the unselected memory unit ME_US. A drain voltage V_D may be applied to the bit line BL (e.g., the second bit line BL2) connected to the selected memory unit ME_S, and a voltage of 0 V may be applied to the bit line BL (e.g., the first and third bit lines BL1 and BL3) connected to the unselected memory unit ME_US.

In the read operation, a sensing current I_tot may flow from the second bit line BL2 to the second source line SL2 by the voltage applied to the word line WL and the bit line BL. In this regard, as shown in Equation 1 below, the sensing current I_tot may correspond to the sum of a current I_S of the selected memory unit ME_S and a current I_US of the unselected memory units ME_US.

$$I\_tot = I\_S + \sum I\_US \qquad Equation ( 1 )$$

FIGS. 8A and 8B are graphs illustrating current-voltage curves of a semiconductor device according to some embodiments. FIG. 8A shows the current-voltage curve obtained with respect to an embodiment EX1, and FIG. 8B shows the current-voltage curve obtained with respect to a comparative example CO1 for comparison.

In the semiconductor device according to some embodiments, the drain area 142 may include a material including a metal or a metal nitride and having a work function equal to or smaller than 4.2 eV. Also, a semiconductor device according to some embodiments has an array structure of a plurality of memory units or a plurality of trap-type transistors as shown in FIG. 7.

Referring to FIG. 8A, the embodiment EX1 has a current-voltage curve with an asymmetrical profile. For example, when a gate voltage has a positive value and gradually increases, the embodiment EX1 has a relatively high drain current value equal to or greater than 10⁻⁴ amperes (A), whereas, when the gate voltage has a negative value and gradually decreases (for example, when the magnitude or absolute value of the voltage gradually increases), the embodiment EX1 has a drain current value equal to or greater than 10⁻⁹ amperes (A), which is relatively low. That is, the embodiment EX1 shows a high current-voltage curve in which a saturation current value (herein referred to as a positive saturation current Isat_p) at a positive gate voltage is significantly higher than a saturation current value (herein referred to as a negative saturation current Isat_n) at a negative gate voltage. In some embodiments, the ratio of the positive saturation current Isat_p to the negative saturation current Isat_n may be in a range of about 100:1 to about 10⁵:1.

In contrast, as shown in FIG. 8B, comparative example CO1 has a current-voltage curve with a symmetrical profile, and has a saturation current value at a positive gate voltage having a value almost similar to or within 10 times the saturation current value at a negative gate voltage. In this case, the ratio of the positive saturation current to the negative saturation current may be in a range of about 1:1 to about 10:1.

Referring to FIG. 8A together with FIG. 7, the selected voltage V_SEL may be applied to the selected memory unit ME_S and the unselected voltage V_USEL may be applied to the unselected memory unit ME_US. For example, the selected voltage V_SEL may be applied to the fifth memory unit ME22 connected to the second bit line BL2 through the second word line WL2, and the unselected voltage V_USEL may be applied to the second memory unit ME12 and the eighth memory unit ME32 connected to the second bit line BL2 through the first word line WL1 and the third word line WL3, respectively.

When the selected memory unit ME_S is in a write state (for example, data 0 state), a first current I_0e (or off current) may flow through the selected memory unit ME_S, and a third current I_2e (or unselected current) may flow through each of the unselected memory units ME_US. For example, when the embodiment EX1 includes a 3×3 array as shown in FIG. 7, the sensing current I_tot through the second bit line BL2 is expressed as Equation (2) below.

$$I\_tot ( write ) = I\_ 0 e + I\_ 2 e + I\_ 2 e \qquad Equation ( 2 )$$

When the selected memory unit ME_S is in an erase state (for example, data 1 state), the second current I_1e (or on current) may flow through the selected memory unit ME_S, and a third current I_2e (or unselected current) may flow through each of the unselected memory units ME_US. For example, when the embodiment EX1 includes a 3×3 array as shown in FIG. 7, the sensing current I_tot through the second bit line BL2 is expressed as Equation (3) below.

$$I\_tot ( erase ) = I\_le + I\_ 2 e + I\_ 2 e \qquad Equation ( 3 )$$

In some embodiments, when the embodiment EX1 includes an m×m array, the sensing current I_tot when the selected memory unit ME_S is in a write state is expressed as Equation (4) below.

$$I\_tot ( write ) = I\_ 0 e + m \times I\_ 2 e ( where m is a natural number ) \qquad Equation ( 4 )$$

In some embodiments, when the embodiment EX1 includes the m×m array, the sensing current I_tot when the selected memory unit ME_S is in an erased state is expressed as Equation (5) below.

$$I\_tot ( erase ) = I\_le + m \times I\_ 2 e ( where m is a natural number ) \qquad Equation ( 5 )$$

According to some embodiments, the unselected voltage V_USEL may be set to a value corresponding to an intersection of a current-voltage curve in the write stage and a current-voltage curve in the erase stage. For example, when the unselected memory unit ME_US is in a write state, the third current I_2e may flow from the unselected voltage V_USEL, and when the unselected memory unit ME_US is in an erase state, the third current I_2e may flow from the unselected voltage V_USEL. Therefore, a difference between the sensing current I_tot(write) when the selected memory unit ME_S is in the write state and the sensing current I_tot(erase) when the selected memory unit ME_S is in the erase state is expressed as Equation (6) below.

$$I\_tot ( write ) - I\_tot ( erase ) = I\_ 0 e - I\_le \qquad Equation ( 6 )$$

As the unselected voltage V_USEL is set to the value corresponding to the intersection of the current-voltage curve of the write stage and the current-voltage curve of the erase stage, regardless of whether the unselected memory unit ME_US is in the write state or the erase state, a sensing operation may be performed based on a difference between an on current and an off current of the selected memory unit ME_S.

Also, according to some embodiments, a difference between an off current (e.g., first current I_0e) and an on current (e.g., second current I_1e) at the selected voltage V_SEL may be relatively large. For example, the ratio of the on current (e.g., the second current I_1e) to the off current (e.g., the first current I_0e) at the selected voltage V_SEL may be in a range of 1000 to 10⁸. Accordingly, a sensing margin of the semiconductor device may be improved by a remarkably large difference between the off current and the on current.

Conversely, in the comparative example CO1, the difference between the off current (e.g., the first current I_0c) and the on current (e.g., the second current I_1c) at the selected voltage V_SEL may be relatively small, and the difference between the third current I_2c and the off current (e.g., the first current I_0c) at the unselected voltage V_USEL and/or the third current I_2c and the on current (e.g., the second current I_1c) may also be relatively small.

As described above, according to some embodiments, regardless of whether the unselected memory unit ME_US is in a write state or an erase state, the sensing operation may be performed based on the difference between the on current and the off current of the selected memory unit ME_S. The difference between the on current and the off current of the selected memory unit ME_S can be referred to as the sensing margin and a greater sensing margin is preferable. In the example embodiment EX1 the difference between the on current and the off current has a significantly large value, and thus, the sensing margin of the semiconductor device of the example embodiment EX1 is improved relative to the sensing margin of the semiconductor device of the comparison example CO1.

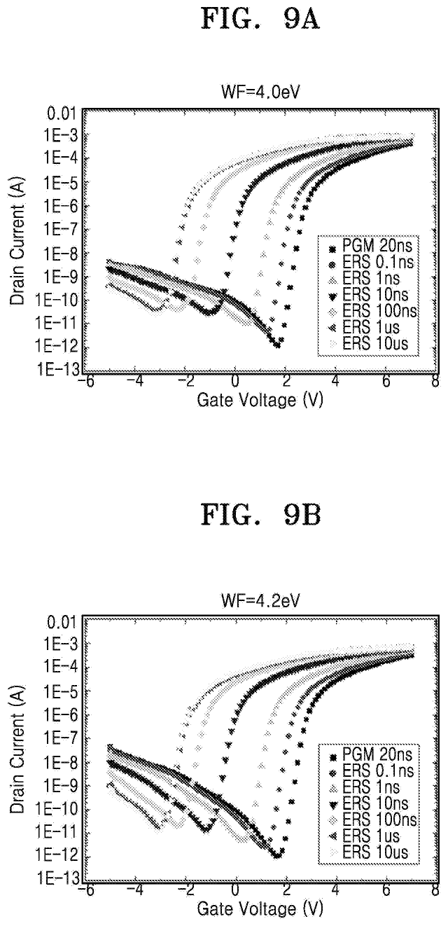

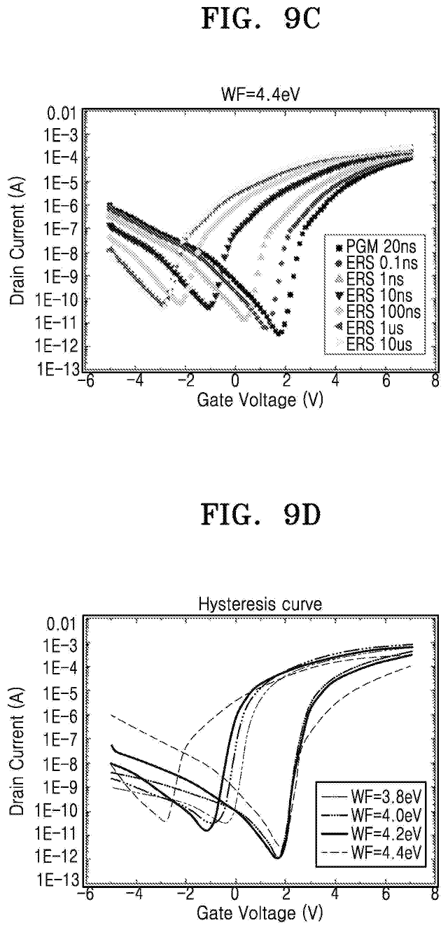

FIGS. 9A to 9D are graphs illustrating current-voltage curves of semiconductor devices according to some embodiments. Specifically, FIG. 9A shows the current-voltage curve of a first embodiment EX21 in which a drain area includes a metal material having a work function of 4.0 eV, and FIG. 9B shows the current-voltage curve of a second embodiment EX22 including a metal material having a work function of 4.2 eV. FIG. 9C shows the current-voltage curve of a comparative example CO2 in which the drain area includes a metal material having a work function of 4.4 eV, and FIG. 9D shows a hysteresis curve according to the work function of the drain area.

As shown in FIGS. 9A and 9B, it may be confirmed that the first embodiment EX21 and the second embodiment EX22 in which the drain area has a work function equal to or smaller than 4.2 eV exhibit asymmetrical current-voltage curves. On the other hand, as shown in FIG. 9C, it may be confirmed that the comparative example CO2 in which the drain area has a work function equal to or greater than 4.4 eV exhibits a current-voltage curve having greater symmetry. Accordingly, it may be confirmed that when the drain area includes a metal or metal nitride having a work function equal to or smaller than 4.2 eV, the semiconductor device may secure a relatively large memory window (e.g., range between the on current and the off current) and have an improved a sensing margin compared to a semiconductor device having a working function greater than 4.2 eV. The hysteresis curve of FIG. 9D further illustrates the relationship between work function, on current, and off current.

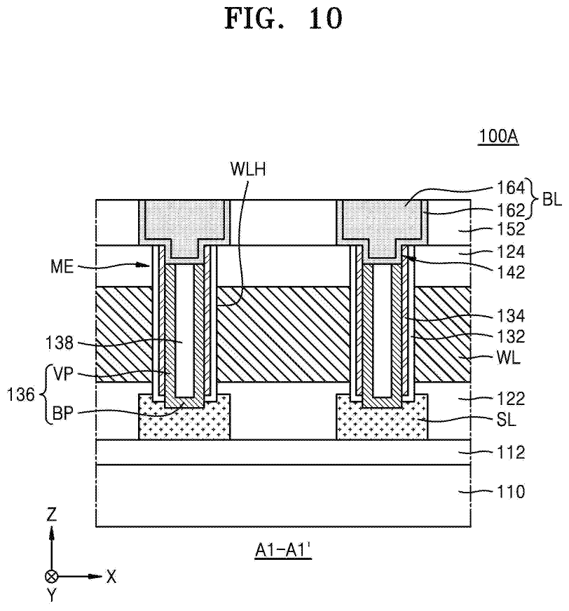

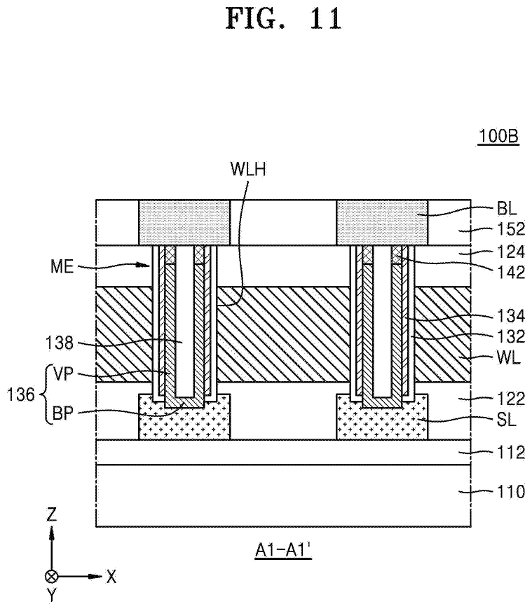

FIG. 10 is a cross-sectional view illustrating a semiconductor device 100A according to some embodiments.

Referring to FIG. 10, the bit line BL may include a conductive barrier 162 and a buried conductive layer 164, and the conductive barrier 162 may be integrally formed with the drain area 142 (e.g., the drain area 142 is a component of the bit line BL, integrally formed with the bit line BL and is not a separate component). For example, the conductive barrier 162 may include a metal or metal nitride having a work function equal to or smaller than 4.2 eV.

The bit line BL may include a part, or portion extending into the word line opening WLH, and the part or portion of the conductive barrier 162 disposed inside the word line opening WLH may be referred to as the drain area 142.

FIG. 11 is a cross-sectional view illustrating a semiconductor device 100B according to some embodiments.

Referring to FIG. 11, the drain area 142 may have an annular horizontal cross section, an inner sidewall of an annulus of the drain area 142 may be in contact with the buried pillar 138, and the outer sidewall of the drain area 142 may be in contact with the trap layer 134. In some embodiments, the drain area 142 may be formed by removing an upper part of the channel layer 136 disposed between the buried pillar 138 and the trap layer 134 and then, filling a metal or metal nitride in a space where the upper part of the channel layer 136 was removed.

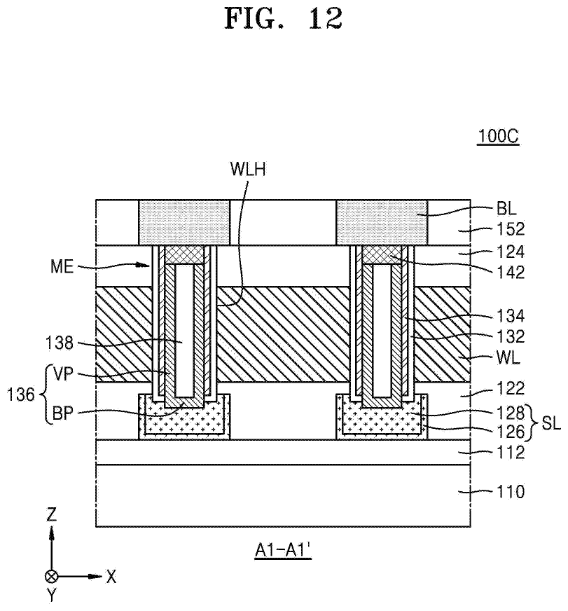

FIG. 12 is a cross-sectional view illustrating a semiconductor device 100C according to some embodiments.

Referring to FIG. 12, the source line SL may include a conductive barrier 126 and a buried conductive layer 128. For example, the conductive barrier 126 and the buried conductive layer 128 may include or be formed of at least one of titanium nitride (TiN), aluminum (Al), thallium (TI), indium (In), cadmium (Cd), hafnium (Hf), manganese (Mn), tantalum (Ta), zirconium (Zr), or tungsten (W).

FIG. 12 shows an example in which the conductive barrier 126 covers a sidewall and a bottom surface of the buried conductive layer 128 and a bottom surface of the channel layer 136 contacts an upper surface of the buried conductive layer 128. However, in some embodiments, the conductive barrier 126 may extend on the upper surface of the buried conductive layer 128 to cover the upper surface of the buried conductive layer 128, and the bottom surface of the channel layer 136 may be disposed to contact an upper surface of the conductive barrier 126.

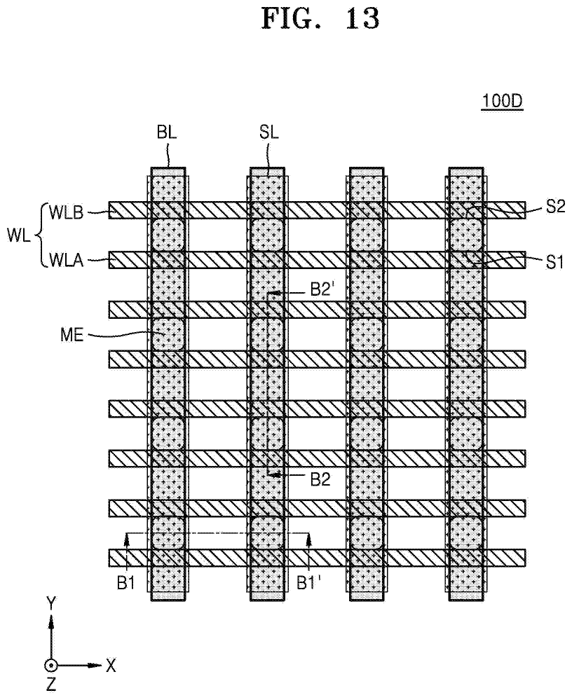

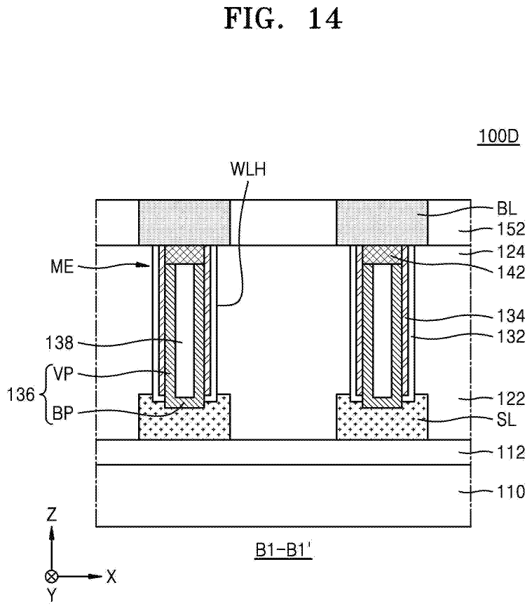

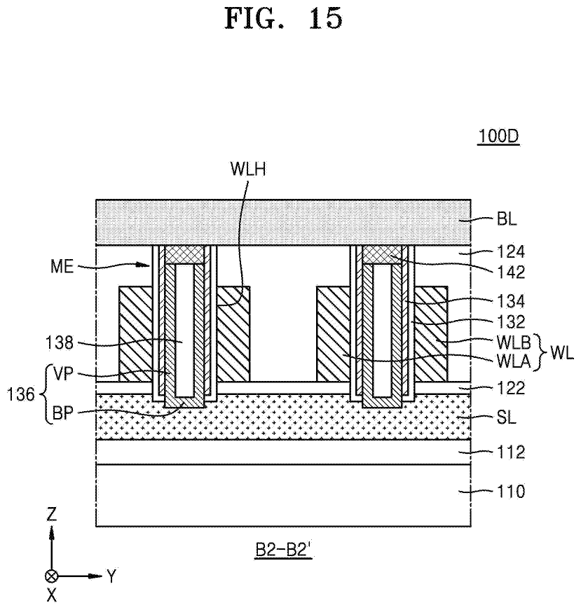

FIG. 13 is a layout diagram illustrating a semiconductor device 100D according to some embodiments, FIG. 14 is a cross-sectional view taken along line B1-B1′ of FIG. 13, and FIG. 15 is a cross-sectional view taken along line B2-B2′ of FIG. 13.

Referring to FIGS. 13 to 15, the semiconductor device 100D may have a dual gate structure. For example, the word line WL may include a first word line WLA disposed on a first sidewall S1 of the memory unit ME and a second word line WLB disposed on a second sidewall S2 of the memory unit ME. The second insulating layer 124 may fill a space between the first word line WLA and the second word line WLB.

FIGS. 13 to 15 illustrate the word line WL of a dual gate structure, but in some embodiments, the word line WL may have a single gate structure, and in this case, the word line WL may include only the first word line WLA disposed on the first sidewall S1 of the memory unit ME (or the word line WL may include only the second word line WLB disposed on the second sidewall S2 of the memory unit ME).

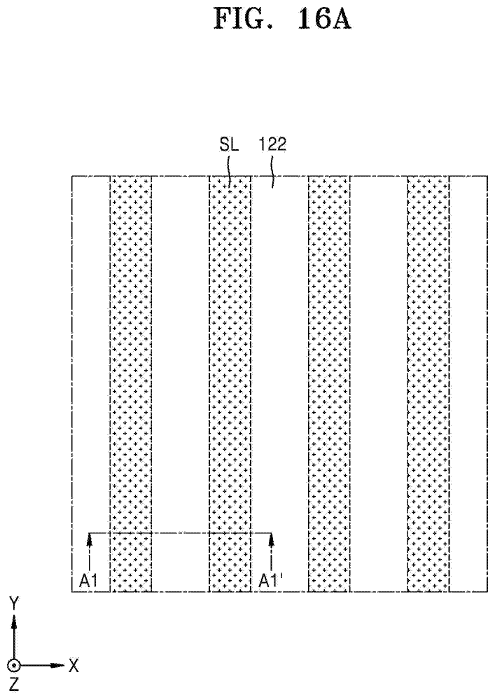

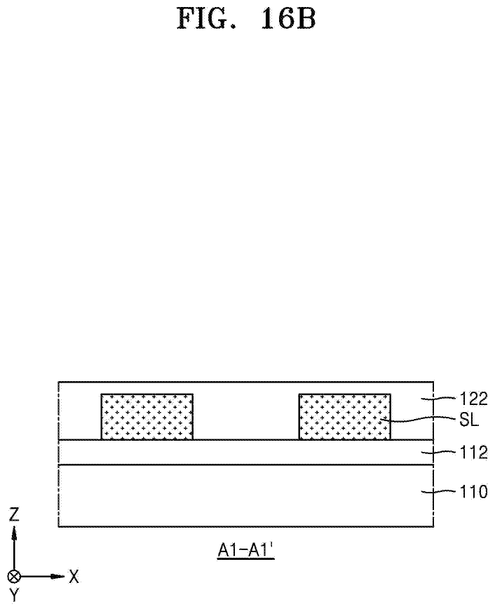

FIGS. 16A to 22 are cross-sectional views illustrating a method of manufacturing the semiconductor device 100 according to some embodiments. Specifically, FIGS. 16A, 17A, and 18A show plan views according to manufacturing processes, and FIGS. 16B, 17B, 18B, and 19 to 22 are cross-sectional views taken along line A1-A1′ of FIG. 16A. In FIGS. 16A to 22, the same reference numerals as in FIGS. 1 to 15 denote the same components.

Referring to FIGS. 16A and 16B, the lower insulating layer 112 is formed on the substrate 110. Thereafter, the plurality of source lines SL extending in the second horizontal direction Y and the first insulating layers 122 filling spaces between the plurality of source lines SL and covering upper surfaces of the plurality of source lines SL may be formed on the lower insulating layer 112.

In some embodiments, the plurality of source lines SL may be formed using p-type impurity-doped polysilicon. In some embodiments, the plurality of source lines SL may include at least one of titanium nitride (TiN), aluminum (Al), thallium (TI), indium (In), cadmium (Cd), hafnium (Hf), manganese (Mn), tantalum (Ta), zirconium (Zr), or tungsten (W).

In some embodiments, the plurality of source lines SL may be formed as a structure including the conductive barrier 126 and the buried conductive layer 128 (see FIG. 12).

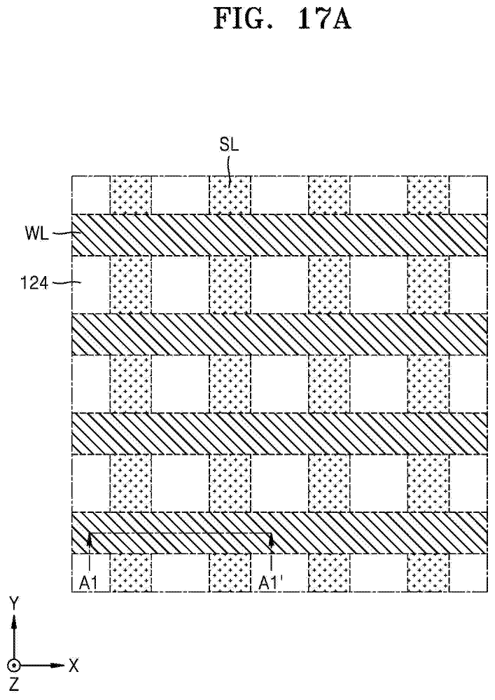

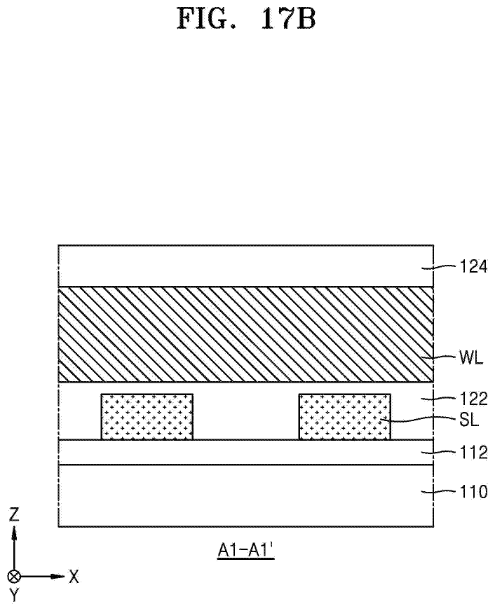

Referring to FIGS. 17A and 17B, the plurality of word lines WL extending in the first horizontal direction X and the second insulating layers 124 filling spaces between the plurality of word lines WL and covering upper surfaces of the plurality of word lines WL may be formed on the plurality of source lines SL and the first insulating layer 122. In some embodiments, the plurality of word lines WL may include doped polysilicon, Ti, TiN, Ta, TaN, W, WN, TiSiN, WSiN, or a combination thereof. The plurality of word lines WL may be spaced apart from the plurality of source lines SL in the vertical direction Z by the first insulating layer 122.

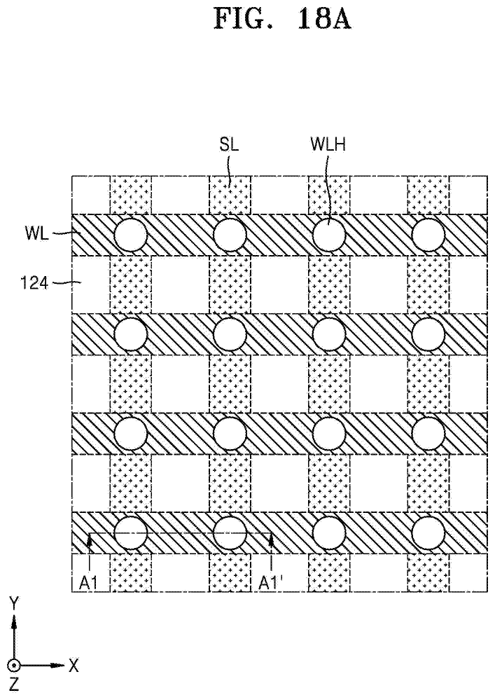

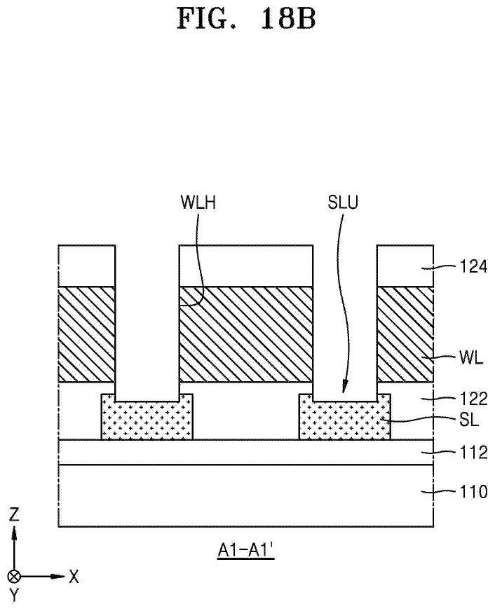

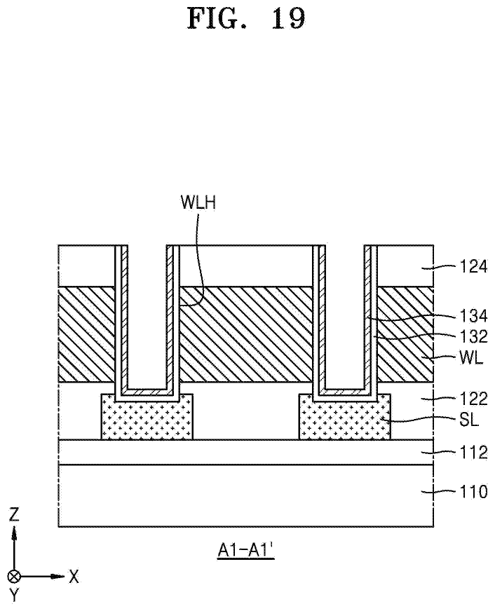

Referring to FIGS. 18A and 18B, the word line opening WLH may be formed by forming a mask pattern (not shown) on the second insulating layer 124 and removing some of the plurality of word lines WL, a part of the second insulating layer 124, and a part of the first insulating layer 122 at intersections of the plurality of word lines WL and the plurality of source lines SL.

The word line opening WLH may have a horizontal cross-sectional shape such as a circle, an oval, a rectangle, a rectangle with rounded corners, etc. The word line opening WLH may be formed to extend in the vertical direction Z through the second insulating layer 124, the word line WL, and the first insulating layer 122, and an upper surface SLU of the source line SL may be exposed at the bottom portion of the word line opening WLH.

Referring to FIG. 19, the gate insulating layer 132 and the trap layer 134 may be sequentially formed on the inner wall of the word line opening WLH.

In some embodiments, the gate insulating layer 132 may include silicon oxide or a high-k dielectric material, and the high-k dielectric material may include hafnium oxide, aluminum oxide, zirconium oxide, titanium oxide, or a combination thereof. The trap layer 134 may include silicon nitride, hafnium oxide, aluminum oxide, yttrium oxide, or a combination thereof. In some embodiments, the gate insulating layer 132 and the trap layer 134 may be formed to a relatively small thickness by which the inside of the word line opening WLH is not completely filled, and may be conformally formed on the inner wall of the word line opening WLH.

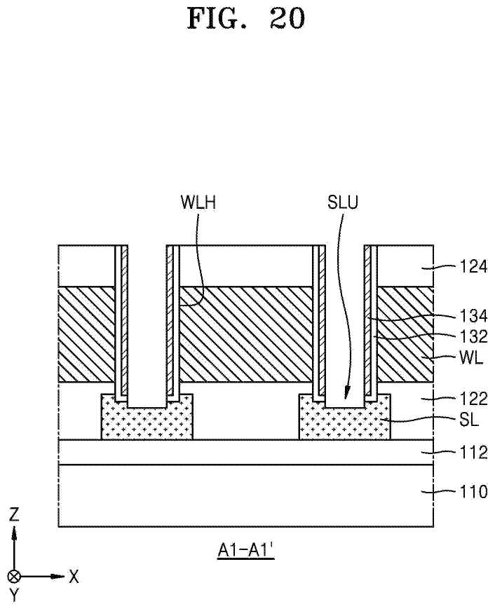

Referring to FIG. 20, the upper surface SLU of the source line SL may be exposed again by removing a part of the gate insulating layer 132 and a part of the trap layer 134 disposed on the bottom portion of the word line opening WLH.

In some embodiments, a process of removing a part of the gate insulating layer 132 and a part of the trap layer 134 may be a dry etching process, a recess process, or an etch-back process. In some embodiments, an upper portion of the source line SL may be further removed by the process of removing a part of the gate insulating layer 132 and a part of the trap layer 134 so that a stepped portion may be formed on the upper surface SLU of the source line SL.

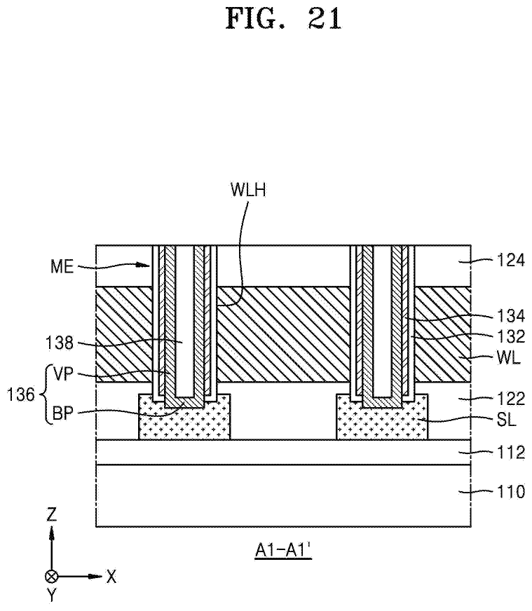

Referring to FIG. 21, the channel layer 136 may be formed on the inner wall of the word line opening WLH. The channel layer 136 may include the bottom portion BP disposed on the upper surface of the source line SL and the vertical extension portion VP integrally connected to the bottom portion BP and extending in the vertical direction Z.

In some embodiments, the channel layer 136 may include at least one of polysilicon, silicon germanium, gallium arsenide, gallium nitride, indium phosphide, graphene, boron nitride, CuS₂, CuSe₂, WSe₂, MoS₂, MoSe₂, WS₂, indium zinc oxide, zinc tin oxide, yttrium zinc oxide, or indium gallium zinc oxide.

Thereafter, a buried pillar 138 may be formed on the inner sidewall of the channel layer 136. An upper surface of the buried pillar 138 may be disposed at the same vertical level as upper surfaces of the channel layer 136 and the second insulating layer 124.

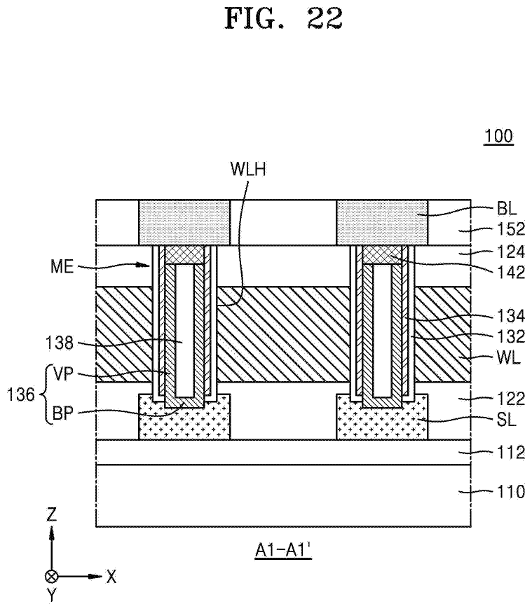

Referring to FIG. 22, the drain area 142 may be formed in a space formed by removing a part of the channel layer 136 and a part of the buried pillar 138 disposed above the word line opening WLH.

In some embodiments, the drain area 142 may be formed using a metal or metal nitride having a work function equal to or smaller than 4.2 eV. In some embodiments, the drain area 142 may include at least one of titanium nitride (TiN), aluminum (Al), thallium (TI), indium (In), cadmium (Cd), hafnium (Hf), manganese (Mn), tantalum (Ta) or zirconium (Zr).

Accordingly, the memory unit ME may be formed inside the word line opening WLH. The memory unit ME may include the gate insulating layer 132, the trap layer 134, the channel layer 136, the buried pillar 138, and the drain area 142, and may be arranged in a matrix form at intersections of the plurality of word lines WL and the plurality of source lines SL.

Thereafter, the plurality of bit lines BL extending in the second horizontal direction Y and the third insulating layers 152 filling spaces between the plurality of bit lines BL may be formed on the drain area 142 and the second insulating layer 124.

In some embodiments, the drain area 142 and a part of the bit line BL may be formed in the same forming process. For example, a part of the conductive barrier 162 of the bit line BL and the drain area 142 may be integrally connected. In this case, the semiconductor device 100A described with reference to FIG. 10 may be formed.

In some embodiments, while the upper side of the channel layer 136 disposed inside the word line opening WLH is removed, the upper side of the buried pillar 138 may not be removed. The drain area 142 may be formed in the space where the upper side of the channel layer 136 is removed, and in this case, the semiconductor device 100B described with reference to FIG. 11 may be formed.

While the inventive concept has been particularly shown and described with reference to embodiments thereof, it will be understood that various changes in form and details may be made therein without departing from the spirit and scope of the following claims.

What is claimed is:

1. A semiconductor device comprising:
a source line extending in a first horizontal direction on a substrate;
a channel layer extending in a vertical direction perpendicular to an upper surface of the substrate, and comprising a first end, a second end opposite to the first end, and a channel layer sidewall extending from the first end to the second end, the first end being disposed on the source line;
a trap layer disposed on the channel layer sidewall;
a gate insulating layer disposed on an outer surface of the trap layer;
a word line disposed on at least one sidewall of the gate insulating layer and extending in a second horizontal direction crossing the first horizontal direction;
a drain area disposed on the second end of the channel layer and comprising a material having a work function equal to or smaller than 4.2 eV; and
a bit line disposed on the drain area and extending in the first horizontal direction.

2. The semiconductor device of claim 1, wherein the drain area includes a material having a work function equal to or smaller than 4.2 eV comprises at least one metal or metal nitride.

3. The semiconductor device of claim 2, wherein the drain area includes at least one of titanium nitride (TiN), aluminum (Al), thallium (TI), indium (In), cadmium (Cd), hafnium (Hf), manganese (Mn), tantalum (Ta), or zirconium (Zr).

4. The semiconductor device of claim 1, wherein the drain area is disposed between the channel layer and the bit line.

5. The semiconductor device of claim 1, wherein
the channel layer has a cylindrical shape extending in the vertical direction, and
the word line surrounds the channel layer when viewed in plan view.

6. The semiconductor device of claim 1, wherein the channel layer includes
a bottom portion at the first end that is disposed on an upper surface of the source line, and
a vertical extension portion extending from the bottom portion towards the second end in the vertical direction, and
the trap layer covers an outer sidewall of the vertical extension portion.

7. The semiconductor device of claim 6, further comprising: a buried pillar disposed on an inner sidewall of the vertical extension portion,
wherein the drain area is disposed on an upper surface of the buried pillar and an upper surface of the vertical extension portion.

8. The semiconductor device of claim 6, wherein a bottom surface of the drain area is disposed at a higher vertical level than an upper surface of the word line relative to an upper surface of the substrate.

9. The semiconductor device of claim 1, wherein the source line comprises p-type dopant-doped polysilicon.

10. The semiconductor device of claim 1, wherein the source line includes at least one of titanium nitride (TiN), aluminum (Al), thallium (Tl), indium (In), cadmium (Cd), hafnium (Hf), manganese (Mn), tantalum (Ta), zirconium (Zr), or tungsten (W).

11. The semiconductor device of claim 1, wherein the semiconductor device is a capacitor-less dynamic random access memory (DRAM) device.

12. A semiconductor device comprising:
a source line extending in a first horizontal direction on a substrate;
a word line disposed at a vertical level higher than the source line and extending in a second horizontal direction crossing the first horizontal direction;
a gate insulating layer disposed on an inner wall of a word line opening penetrating the word line and extending in a vertical direction perpendicular to an upper surface of the substrate;
a trap layer disposed on the gate insulating layer disposed on the inner wall of the word line opening;
a channel layer disposed on the trap layer disposed on the gate insulating layer disposed on the inner wall of the word line opening and having a part in contact with an upper surface of the source line on a bottom portion of the word line opening;
a drain area disposed at a vertical level higher than the word line, contacting an upper surface of the channel layer, and comprising a material having a work function equal to or smaller than 4.2 eV; and
a bit line disposed on the drain area and connected in the first horizontal direction.

13. The semiconductor device of claim 12, wherein
the drain area includes a metal or metal nitride, and
includes at least one of titanium nitride (TiN), aluminum (Al), thallium (TI), indium (In), cadmium (Cd), hafnium (Hf), manganese (Mn), tantalum (Ta), or zirconium (Zr).

14. The semiconductor device of claim 12, wherein the channel layer has a cylindrical shape extending in the vertical direction.

15. The semiconductor device of claim 12, wherein the channel layer includes
a bottom portion disposed on the upper surface of the source line, and
a vertical extension portion extending in the vertical direction on the bottom portion, and
the trap layer covers an outer sidewall of the vertical extension portion.

16. The semiconductor device of claim 15, further comprising: a buried pillar disposed on an inner sidewall of the vertical extension portion,
wherein the drain area is disposed on an upper surface of the buried pillar and an upper surface of the vertical extension portion.

17. The semiconductor device of claim 12, wherein the source line comprises p-type dopant-doped polysilicon.

18. The semiconductor device of claim 12, wherein the semiconductor device comprises a capacitor-less dynamic random access memory (DRAM) device.

19. A semiconductor device comprising:
a plurality of source lines extending in a first horizontal direction on a substrate;
a plurality of word lines respectively disposed at a vertical level higher than the plurality of source lines and extending in a second horizontal direction crossing the first horizontal direction;
a plurality of bit lines respectively disposed at a vertical level higher than the plurality of word lines and extending in the first horizontal direction; and
a plurality of memory units respectively disposed at intersections of the plurality of word lines and the plurality of bit lines;
wherein each of the plurality of memory units comprises,
a channel layer extending in a vertical direction perpendicular to an upper surface of the substrate and contacting an upper surface of a source line of the plurality of source lines;
a trap layer disposed on an outer wall of the channel layer;
a gate insulating layer disposed on an outer wall of the trap layer and surrounded by a word line of the plurality of word lines; and
a drain area disposed on an upper surface of the channel layer and below each of the plurality of bit lines and including a metal or metal nitride.

20. The semiconductor device of claim 19, wherein
the drain area includes a material having a work function equal to or smaller than 4.2 eV, and
the drain area includes at least one of titanium nitride (TiN), aluminum (Al), thallium (TI), indium (In), cadmium (Cd), hafnium (Hf), manganese (Mn), tantalum (Ta), or zirconium (Zr).
